(19) United States
(12) Patent Application Publication
(10) Pub. No.: US 2013/0180850 A1
(43) Pub. Date: Jul. 18, 2013

(54) MAGNETRON SPUTTERING APPARATUS

(71) Applicants: Hartmut Rohrmann, Schriesheim (DE); Martin Dubs, Maienfeld (CH)

(72) Inventors: Hartmut Rohrmann, Schriesheim (DE); Martin Dubs, Maienfeld (CH)

(73) Assignee: OC OERLIKON BALZERS AG, Balzers (LI)

(21) Appl. No.: 13/808,956

(22) PCT Filed: Jul. 8, 2011
(86) PCT No.: PCT/EP2011/003413

§ 371 Date: Apr. 8, 2013

Related U.S. Application Data
(60) Provisional application No. 61/362,870, filed on Jul. 9, 2010.

(51) Int. Cl. C23C 14/35

(52) U.S. Cl. CPC C23C 14/352
USPC 204/298.11

(57) ABSTRACT

A magnetron sputtering apparatus comprises, within a vacuum chamber (1), a substrate support (2) holding a substrate (3) with an upward-facing plane substrate surface (4) which is to be coated. The substrate (3) may be a disk of, e.g., 200 mm diameter. At a distance from a centre plane (5) two oblong targets (7a, 7b) are symmetrically arranged which are inclined towards the centre plane (5) so as to enclose an acute angle (β; −β) of between 8° and 35° with the plane defined by the substrate surface (4). Above the substrate surface (4) a collimator (13) with equidistant rectangular collimator plates is arranged. With this configuration high uniformity of the coating is achievable, in particular, if the distance of the collimator (13) from the substrate surface (4) is chosen as a multiple n of the extension of the collimator (13) perpendicular to the said surface, preferably with n equalling 1 or 2, for suppressing ripple.

### FIELD OF THE INVENTION

The invention concerns a magnetron sputtering apparatus according to the preamble of claim 1, where the apparatus comprises a substrate support defining a plane substrate surface within a substrate plane, with a longitudinal centre plane perpendicularly intersecting the substrate surface along a longitudinal centre line, for carrying a substrate, a target assembly with two substantially oblong targets arranged in parallel above the substrate support at opposite sides of the longitudinal centre plane, each target having a target plate with a target surface facing the substrate surface and extending beyond boundaries of the same in the longitudinal direction and and a magnet configuration arranged at a backside of the target plate opposite the target surface.

Apparatus of this type are used to cover a surface of a substrate with a thin film of a material released from target surfaces of a target assembly. The substrate is then usually cut into rectangular chips which are used in the production of semiconductor devices and other items.

### PRIOR ART

A magnetron sputtering apparatus of the generic type is known from U.S. Pat. No. 5,415,757 A. It is a general problem with this type of sputtering apparatus that the thickness of the film formed on the surface of the substrate tends to vary considerably, often by 10% and more over a target having a diameter of, e.g., 200 mm, leading to variable properties of products cut from the substrate. To some extent the thickness can be equalised by permanently rotating the substrate, however, this requires a rotatable support and renders the apparatus more complicated and expensive, in particular, as the substrate and target assembly must be accommodated in a vacuum chamber.

It is also known to provide a collimator between a single target and a substrate in order to form a magnetic layer with a preferred direction of magnetisation as explained, e.g., in WO 2008/080 244 A1. However, used together with known target assemblies the collimator does not cause a significant improvement of the uniformity of the film layer, in particular, with respect to its thickness.

It is the object of the invention to provide a magnetron sputtering apparatus which allows the formation of films whose thickness varies comparatively little over the substrate surface, with no necessity of permanently rotating or otherwise moving the substrate with respect to the target during the sputtering process.

### SUMMARY OF THE INVENTION

This object is achieved by the additional features contained in the characterising portion of claim 1, namely that each target plate is inclined with respect to the substrate plane towards the centre plane about a longitudinal axis such that the surface normal of the target surface at a centre point of the target surface is substantially directed towards the substrate surface in each case, the target surfaces of the target plates enclosing an angle smaller than 180°, and at least one collimator with substantially plane parallel collimator plates extending in a lateral direction substantially perpendicular to the longitudinal centre plane is provided which is placed between each target surface and the substrate surface.

It has been found that with magnetron sputtering apparatus according to the invention it is possible to depose a thin film on a relatively large substrate, e.g., as mentioned above, on a disk 200 mm in diameter, whose thickness only deviates by 2 to 4% or less from a mean, depending on various parameters. It has also turned out that the thickness distribution hardly changes over target lifetime. Such results are usually achievable without the need of permanently rotating the substrate support during the sputtering process which in many cases may even remain fixed, reducing the complexity of the apparatus.

### BRIEF DESCRIPTION OF THE DRAWINGS

In the following the invention is explained in more detail with reference to figures which only show embodiments.

FIG. 1a schematically shows a front view of a magnetron sputtering apparatus according to a first embodiment of the invention,

FIG. 1b schematically shows a top view of the embodiment of FIG. 1a,

FIG. 2a schematically shows a front view of a magnetron sputtering apparatus according to a second embodiment of the invention,

FIG. 2b schematically shows a top view of the embodiment of FIG. 2a,

FIG. 3 schematically shows a partial sectional view of the embodiment of FIGS. 2a,b, and

FIG. 4 shows diagrams illustrating the result of a sputtering process carried out with the embodiment of FIGS. 2a,b,c.

### DESCRIPTION OF THE PREFERRED EMBODIMENTS

The magnetron sputtering apparatus comprises a vacuum chamber 1 and, close to the bottom of the same, a substrate support 2, which is preferably essentially fixed but may also be mounted so as to be laterally displaceable and rotatable. It is configured to hold a substrate 3 exhibiting a plane substrate surface 4 which defines a substrate plane and has a specific shape. In the case described the substrate 3 is a disc with a diameter of, e.g., 200 mm and the substrate surface is therefore a circle with the same diameter. But plane substrates of other shapes, e.g., quadratic ones, are equally possible. The diameter of the substrate is usually between 100 mm and 305 mm.

At opposite sides of a longitudinal centre plane 5 which intersects the substrate surface 4 along a longitudinal centre line 6 two targets 7a,b of a target assembly are arranged above the substrate 3. Each target 7a;b comprises a target plate 8a;b exhibiting a substantially plane target surface 9a;b which faces the substrate surface 4. At the back side opposite the target surface 9a;b a magnet configuration 10a;b is mounted which produces a magnetic field in front of the respective target surface 9a;b. Each target plate 8a,b is substantially oblong, in particular, rectangular or oval, and extends beyond the boundary of the substrate surface 4 in the longitudinal direction. Preferably, each target plate 8a,b comprises an oblong first part which forms a central part of the target surface 9a;b and a ring-shaped second part which forms a second part of the target surface 9a;b surrounding the first part and separated from the same by a slit. A first pole of the magnet configuration 10a;b is arranged at a back of the first part and an opposite pole at a back of the second part. As it has to bridge the slit the magnetic field is forced out into the space in front of the target surface 9a;b, enhancing the formation of target-eroding plasma there. The target plate can, however, be more complex and consist of more than two parts.

At the beginning of the sputtering process the target surfaces 9a,b are plane or have some other initial profile. During the sputtering the target plate is eroded and part of the removed material deposed on the substrate surface 4 where it forms a thin film. The erosion of the target plates 8a,b takes in each case place mostly along a racetrack-shaped closed line forming a corresponding groove in the target surface 9a;b.

The target assembly is preferably but not necessarily symmetrical with respect to the centre plane 5. A centre point 11a;b of the target surface 9a;b is, in a lateral direction, separated from the centre plane 5 by an eccentricity x and from the substrate plane by an elevation d. The eccentricity x is usually between 80 mm and 150 mm and preferably between 100 mm and 130 mm whereas the elevation d is normally between 70 mm and 250 mm. Each target 7a,b is, about a longitudinal axis 12a;b which passes through the centre point 11a;b, inclined towards the centre plane 5, in such a way that it defines a plane which encloses an acute angle β, which may be between 8° and 35°, with the substrate plane, planes defined by the two target surfaces 9a,b enclosing an angle smaller than 180°, i.e., an angle of 180° −2β.

At least one collimator is provided and placed between the target assembly and the substrate, the collimator consisting of substantially plane parallel collimator plates extending in a lateral direction, i.e., each substantially coinciding with a plane perpendicular to the substrate plane 4 as well as to the centre plane 5, two neighbouring plates always laterally delimiting a slot directed towards the substrate plane and substantially perpendicular to the longitudinal centre line 6.

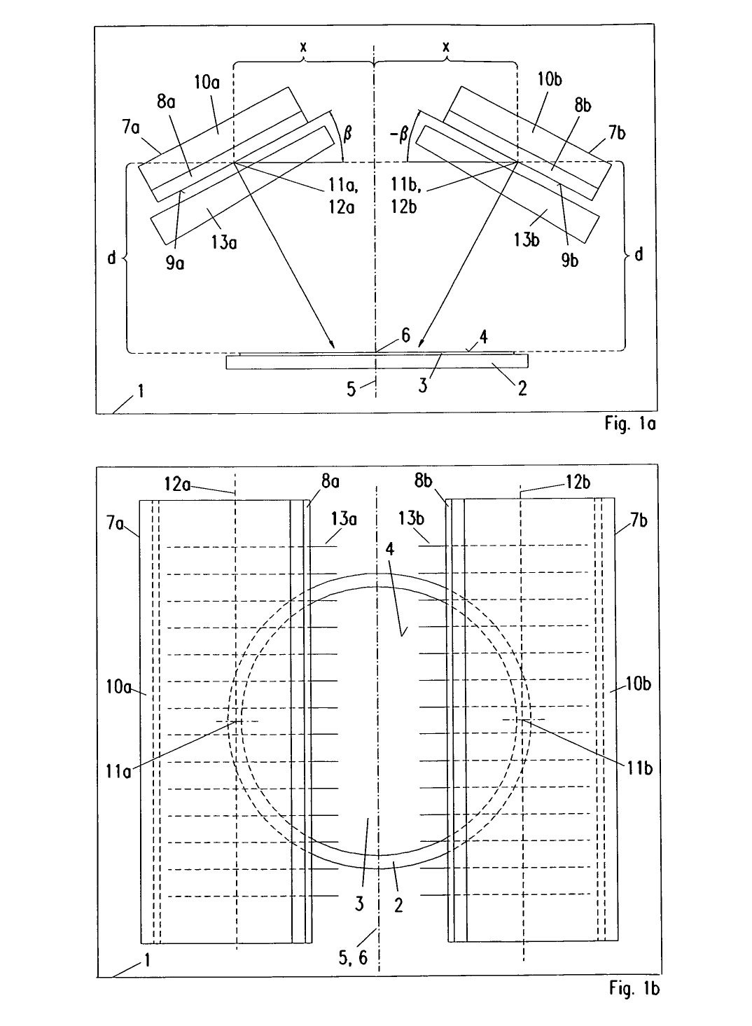

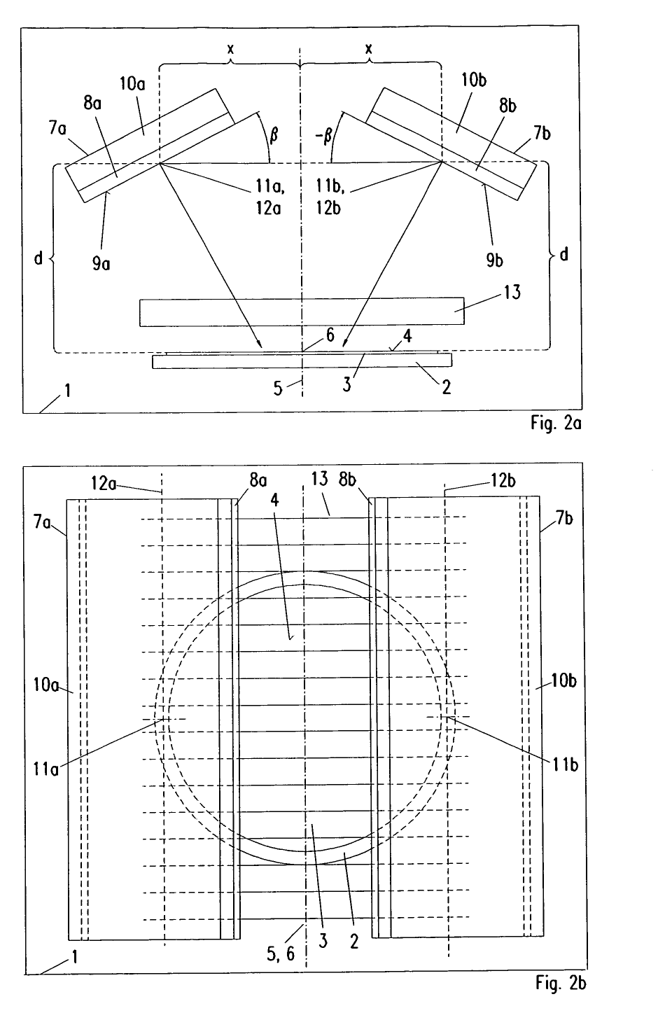

In the first embodiment shown in FIG. 1a,b two separate collimators 13a,b are arranged each at a distance in front of the respective target surface 9a;b, each consisting of a row of, e.g., equidistant, rectangular plates or, as shown, trapezoidal plates whose extensions in a direction perpendicular to the target surface 9a;b increase or decrease with the distance from the centre plane 5. The collimators 13a,b are each inclined by the same angle β or −β, respectively, as the target 7a;b such that an upper edge of each plate is substantially parallel to the target surface 9a;b. The extension of the collimator plates in a lateral direction perpendicular to the centre plane 5 may also vary with the longitudinal distance from the centre points 11a,b of the target surfaces 9a;b.

In the second embodiment a single collimator 13 is arranged at a distance in front of the substrate surface 4. The equidistant collimator plates are substantially plane and rectangular, each with a lower edge extending in the lateral direction, i.e., perpendicular to the centre plane 5 and substantially parallel to the substrate surface 4. Again, the extension of the collimator plates in the lateral direction may vary, e.g., decrease with the longitudinal distance from the centre point 11a;b of the target surface.

In both embodiments the aspect ratio, i.e., the depth of the slot divided by its width, of the collimators or collimator may be somewhat variable, but is preferably between 0.3 and 2.5 everywhere.

In the first embodiment, there is, due to the rather large distance between the collimators 13a,b from the substrate surface 4, no discernable ripple, i.e., variation of the thickness caused by shadowing effects of individual collimator plates.

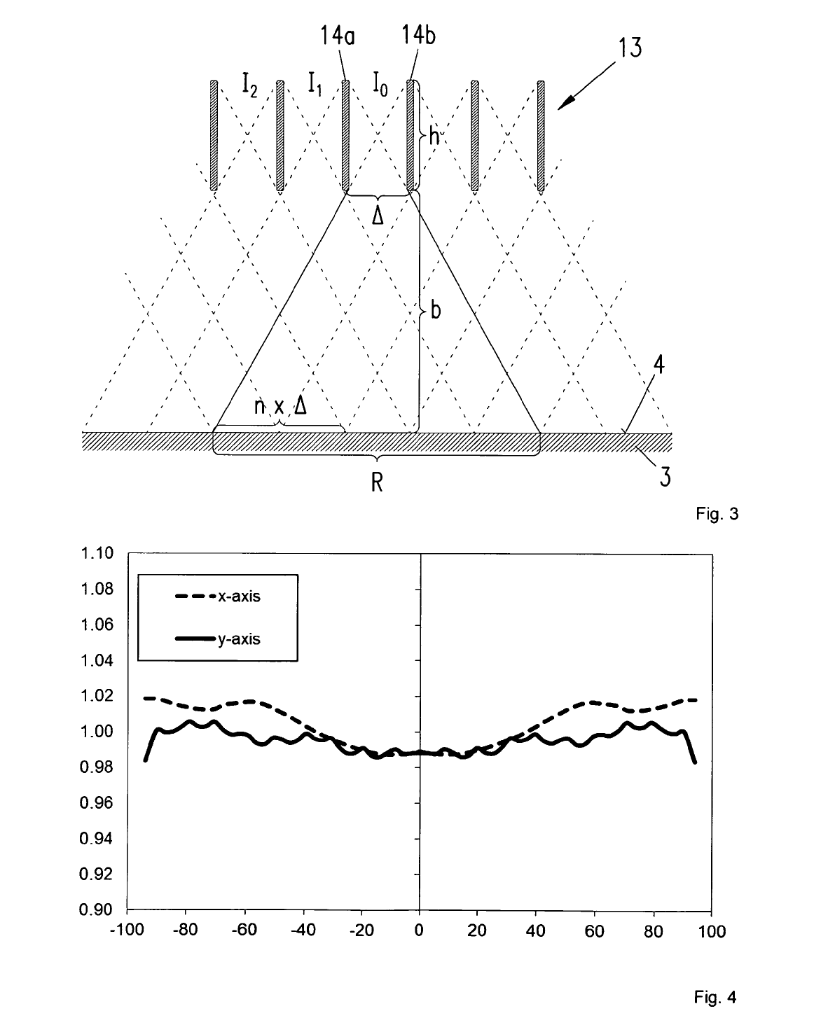

In the second embodiment, on the other hand, with the lower edges of the collimator plates fairly close to the substrate surface 4, ripple can cause considerable variations in the thickness of the coating layer. It has (s. FIG. 3) been found, however, that this effect can be substantially reduced by choosing the distance b between the collimator 13 and the substrate surface 4 and the extension h of the collimator plates perpendicular to the substrate surface 4 in such a way that the region R of the substrate surface 4 which can be reached by particles whose straight trajectories pass through a slot I₀ formed between two neighbouring plates 14a, 14b is a union of strips formed by the normal projections of the said slot I₀ and adjacent slots I₁, I₂. In other words, the said region R of the substrate surface 4 must in each case be laterally bounded on both sides by a normal projection of a collimator plate.

As

h/Δ=(h+b)/(1+n)A (1)

where n is the number of strips corresponding to the projections of adjacent slots on one side this condition is fulfilled where

b=n×h (2)

where n is a natural number and preferably equals 1 or 2.

Uniformity of the coating thickness can be further improved by slightly increasing the thickness of each collimator plate with increasing distance from the centre plane 5.

For example, a collimator plate may have an extension perpendicular to the substrate surface 4 of 20 mm and a thickness at the centre of 0.4 mm and at the lateral ends of 0.5 mm.

FIG. 4 shows the thickness of the coating divided by the mean thickness as a function of the distance from the centre along a y-axis which follows the centre line 6 and along a perpendicular, i.e., laterally extending x-axis. The targets used were NiFe (78.5/21.5) targets. The collimator had an aspect ratio of 2.0, n was chosen to equal 2. The deviation of the thickness from the mean was everywhere less than 2%. The ripple along the y-axis is clearly visible but obviously very small.

### LIST OF REFERENCE SYMBOLS

1 vacuum chamber
2 substrate support
3 substrate
4 substrate surface
5 centre plane
6 centre line
7a,b targets
8a,b target plates
9a,b target surfaces
10a,b magnet configuration
11a,b centre points
12a,b centre lines
13 collimator
13a,b collimators
14a,b plates

What is claimed is:

1-16. (canceled)

17. A magnetron sputtering apparatus comprising:
a substrate support (2) defining a plane substrate surface (4) within a substrate plane, with a longitudinal centre plane (5) perpendicularly intersecting the substrate surface (4) along a longitudinal centre line (6), for carrying a substrate (3),
a target assembly with two substantially oblong targets (7a, 7b) arranged in parallel above the substrate support (2) at opposite sides of the longitudinal centre plane (5), each target (7a, 7b) having a target plate (8a; 8b) with a target surface (9a; 9b) facing the substrate surface (4), the target plate (8a; 8b) being inclined with respect to the substrate plane towards the centre plane (5) about a longitudinal axis such that the surface normal of the target surface (9a; 9b) at a centre point (11a; 11b) of the target surface (9a; 9b) is substantially directed towards the substrate surface (4) in each case, the target surfaces (9a, 9b) of the target plates enclosing an angle smaller than 180°, and a magnet configuration (10a; 10b) arranged at a backside of the target plate (8a; 8b) opposite the target surface (9a; 9b), each target plate (8a, 8b) extending beyond boundaries of the target surface (4) in the longitudinal direction, and
a single collimator (13) with substantially plane parallel collimator plates extending in a lateral direction substantially perpendicular to the longitudinal centre plane (5) arranged at a distance in front of the substrate surface (4) such that the distance (b) of the collimator (13) from the substrate surface (4) is substantially a multiple of the extension (h) of the collimator (13) in a direction perpendicular to the substrate surface (4).

18. The magnetron sputtering apparatus of claim 17, where the distance (b) of the collimator (13) from the substrate surface (4) is once or twice the extension (h) of the collimator (13) in a direction perpendicular to the substrate surface (4).

19. The magnetron sputtering apparatus of claim 17, the apparatus being symmetrical with respect to the centre plane (5).

20. The magnetron sputtering apparatus of claim 17, where an eccentricity (x) which is the distance of the centre point (11a; 11b) of each target surface (9a, 9b) from the centre plane (5) is between 80 mm and 150 mm, preferably between 100 mm and 130 mm.

21. The magnetron sputtering apparatus of claim 17, where an elevation (d) which is the distance of the centre point (11a; 11b) of each target surface (9a, 9b) from the substrate plane is between 70 mm and 250 mm.

22. The magnetron sputtering apparatus of one of claim 17, where the absolute value of the inclination (β; −β) of each target surface (9a, 9b) with respect to the substrate plane is between 8° and 35°.

23. The magnetron sputtering apparatus of one of claim 17, where the substrate surface (4) has a diameter of between 100 mm and 305 mm.

24. The magnetron sputtering apparatus of claim 17, where the collimator plates are substantially perpendicular to the substrate plane.

25. The magnetron sputtering apparatus of claim 17, where the collimator plates are substantially rectangular, with a lower edge substantially parallel to the substrate surface (4).

26. The magnetron sputtering apparatus of claim 17, where the thickness of each collimator plate increases in the lateral direction as a function of the distance from the centre plane (5).

27. The magnetron sputtering apparatus of claim 17, where the aspect ratio of the collimator (13) is everywhere between 0.3 and 2.5.

28. The magnetron sputtering apparatus of claim 17, the target plate (8a, 8b) consisting in each case of at least a first portion and a second portion which surrounds the first portion and is separated from the same by a slit, with a first magnetic pole of the magnet configuration (10a; 10b) placed at a back of the first portion and a second magnetic pole of the magnet configuration placed at a back of the second portion.

29. The magnetron sputtering apparatus of claim 17, the apparatus further comprising a vacuum chamber (1) wherein the substrate support (2), the target assembly and the collimator (13) are accommodated.
